(19) United States
(12) Patent Application Publication
(10) Pub. No.: US 2026/0317247 A1
(43) Pub. Date: Oct. 15, 2026

(54) SI- AND AL/SI-CONTAINING TOP COATINGS

(71) Applicant: OERLIKON SURFACE SOLUTIONS AG, PFÄFFIKON, PFÄFFIKON (CH)

(72) Inventors: Sophie RICHTER, WIEN (AT); Beno WIDRIG, BAD RAGAZ (CH); Oliver HUNOLD, BERGISCH GLADBACH (DE); Lukas ZAUNER, WIEN (AT); Jürgen RAMM, MAIENFELD (CH); Helmut RIEDL-TRAGENREIF, KIRCHBERG AM WALDE (AT)

(21) Appl. No.: 19/484,610

(22) PCT Filed: May 17, 2024
(86) PCT No.: PCT/EP2024/063821

§ 371 Date: Nov. 14, 2025

Related U.S. Application Data
(60) Provisional application No. 63/502,745, filed on May 17, 2023.

(51) Int. Cl. C04B 41/52; C04B 41/00; C04B 41/45; C04B 41/50; C04B 41/87; C04B 41/89; C23C 28/04

(52) U.S. Cl. CPC C04B 41/52; C04B 41/009; C04B 41/4531; C04B 41/5024; C04B 41/5035; C04B 41/5066; C04B 41/507; C04B 41/5096; C04B 41/87; C04B 41/89; C23C 28/042

(57) ABSTRACT

A coated substrate having a coated surface formed by a surface of a substrate and a coating on the substrate surface. The coating includes at least one Si-containing coating film and a base coating film between the substrate and the Si-containing coating film. The base coating film is applied between the substrate and the Si-containing coating film. The Si-containing coating film includes at least two Si-containing layers, where a first Si-containing layer is closer to the base coating film than a second Si-containing layer. Also described is a method for producing a coated substrate.

The present invention relates to silicon containing top coatings (Si-containing top coatings) which can also be produced as aluminum and silicon containing coatings (hereafter also called Al/Si-containing top coatings or simply called Si-containing top coatings) for protecting oxidation-prone materials, i.e. to protect surfaces of materials that are prone to oxidation.

The inventive coatings are particularly useful for protecting TMB_{2+z} films with 0≤z≤1, preferably 0.75≥z≥0, more preferably 0.70>z≥0 (TM is used as shortcut for transition metal or transition metals) against high-temperature oxidation, wherein TM is preferably one or more from tungsten, titanium, and hafnium (one or more from W, Ti and Hf), more preferably TM is Ti and/or Hf.

The present invention relates furthermore to the coated substrates produced by using the above-mentioned Si-containing top coatings (respectively Al/Si-containing coatings) and to a process for reactively grown of such inventive Si containing coatings (respectively Al/Si containing coatings as already mentioned above).

### TECHNICAL FIELD

Decreasing the environmental footprint is of utmost importance when striving for more sustainable industrial processes and products. Besides the focus on decarbonization and reduced primary energy consumption, extending the lifetime of high-performance components is considered as a highly efficient approach to improve sustainability. In this context, physical vapor deposited protective coatings offer attractive possibilities to extend the operating ranges of highly stressed materials by enhancing the surface hardness, corrosion, and wear resistance, and particularly the high-temperature oxidation resistance.

Research on novel protective coatings withstanding extreme mechanical and thermal loads is strongly focused on the class of ultra-high temperature (UHT) ceramics such as transition metal (TM) borides. In addition to their outstanding thermal stability (TM beyond 3000 °C), these UHT borides also feature excellent wear and creep resistance, as well as super-hardness and chemical inertness. Their suitability for applications under extreme conditions is proven by today's use in e.g., atmospheric reentry vehicles, gas turbine combustors, or rocket engine nozzles.

Despite their outstanding mechanical properties, the application of TM diborides as protective thin films is typically limited due to their poor oxidation resistance, related to the competitive formation of both volatile boron and porous TM-oxides. For unalloyed diboride based thin films, the volatilization of B₂O₃ as well as the porous TM-oxide formation is predominantly observed between 400 to 800 °C. Interestingly, for bulk TM-diborides the reported temperature ranges are shifted to higher ranges, as the prevalent mechanisms are slightly different. In the temperature regime below 1000 °C, bulk TM-diborides tend to form unprotective laminated scales consisting of diverse TM-B—O and B₂O₃ domains. In a glassy state B₂O₃ can provide a certain oxidation resistance, but the oxidation kinetics are solely determined by the O₂ diffusion through the B₂O₃ layer. In the temperature range above 1000 °C two simultaneous effects are generally observed. While the partly protective B₂O₃ scale starts to evaporate, the exposed TM forms a non-protective porous TM-oxide scale, allowing for further fast-track oxygen inward diffusion harming the material. The difference between bulk materials and thin films, is strongly related to the typically observed B-rich tissue phase in TM diboride based films accelerating the volatilization. To improve the oxidation resistance of bulk TM diborides, an approach via co-sintering of Si-based compounds (e.g., SiC, MoSi₂, etc.) is commonly selected. This enhances the oxidation resistance significantly through the formation of a dense SiOₓ-based scale. Similarly, for PVD synthesized TM-diboride thin films Al- and Si-based alloying concepts have also shown great potential in improving the high-temperature oxidation behavior. Contrary to bulk materials, this usually targets the formation of diboride-based solid solutions to maintain sufficiently high mechanical properties. In spite it is known that Si alloying in TMB₂ increases the oxidation onset temperature by around 400 °C providing long-term oxidation resistance at 1200 °C up to 100 h, TiB₂ thin films alloyed with Al have been investigated up to 800 °C, where the oxide scale formation could be decreased by 75% for 0.5 h. Especially at long durations, a disadvantage of solid-solution alloying routes is the pore formation within the unaffected coating, associated with the outward diffusion of the added oxide formers (e.g., Si, Al) supplying the protective scale. As an alternative approach towards enhanced oxidation resistant TM diborides, sputtered multilayers of TiB₂/Cr—with Cr acting as strong oxide former have been investigated. However, for this approach, only an improved oxidation behavior in the low-temperature range at 500-600 °C is known.

### Objective of the Present Invention

The main objective of the present invention is providing a coating solution that allows attaining oxidation-resistant TM diboride coatings without having the negative effect of pore formation.

### Technical Solution According to the Present Invention

The objective of the present invention is attained by providing an alternative architectural approach, which allows to prevent the thermal oxidation by applying protective layers on top of the TM diborides (transition diboride films).

Particularly, according to a first aspect of the present invention a coated substrate is provided having a coated surface being formed by a surface of a substrate and a coating provided on said substrate surface, the coating comprising at least one Si-containing coating film and a base coating film deposited between the substrate and the Si-containing coating film, wherein the base coating film is applied between the substrate and the Si-containing coating film, wherein the Si-containing coating film comprises at least two Si-containing layers, a first Si-containing layer and a second Si-containing layer, wherein the first Si-containing layer is deposited closer to the base coating film than the second Si-containing layer, and wherein the first Si-containing layer is a silicon-containing interface layer deposited directly on the outermost surface of the base coating film, thereby preventing oxidation of the base film, wherein
the first Si-containing layer:
   comprises mainly silicon, i.e. contains more than 50 at. % of silicon, or
   consists essentially of silicon, i.e. contains 99.90 at. % or more of silicon,
      and
the second Si-containing layer comprises as main components, i.e. more than 50 at. %:
   Si and O, or
   Si, O and N, or
   Al, Si and O, or
   Al, Si, O and N, or
   Al, Si and N.
      and
the base coating film:
   comprises at least one layer of TMB_{2+z} where:
      TM is one or more transition metals, preferably one or more of Ti, Hf and W, preferably one or more of Ti and Hf,
      B is boron,
      z is in a range of 0≤z≤1, preferably 0≤z≤0.75.

It is particularly conceivable, that
the first Si-containing layer having a layer thickness th₂₁₀ between 30 nm and 30 μm, i.e. 30 μm≥th₂₁₀≥30 nm, and
the second Si-containing layer having preferably a layer thickness thicker than the first Si-containing layer thickness, i.e. th₂₂₀>th₂₁₀.

Preferably, the first Si containing layer may contain diffraction peaks corresponding to pure Si, suggesting that the Si interlayer is indeed in a partially crystalline state.

Furthermore, it is conceivable that the second Si-containing layer is in X-ray amorphous state.

Furthermore, it can be provided that the second Si-containing layer is deposited atop the first Si-containing layer, and preferably the second Si-containing layer is a protection layer of the type of silicate layer, more preferably of the type rare earth silicate layer.

Furthermore, it can be provided that the substrate is selected from one of the following kinds of substrates: carbon substrates, boron-rich substrates, substrates comprising composite materials, substrates consisting of or comprising silicon carbides, zircon carbides, hafnium carbides, boron carbides, and/or other carbides.

Furthermore, it can be provided that the second Si-containing layer:
comprises mainly, i.e. contains more than 50 at. %, of at least one of following compounds:
   silicon oxide,
   aluminum silicon oxide, and
   aluminum silicon nitride, or
consists essentially, i.e. contains 99.90 at. % or more of at least one of following compounds:
   silicon oxide,
   aluminum silicon oxide, and
aluminum silicon nitride.

Furthermore, it can be provided that the second Si-containing layer is:
a Si—O layer, or
an Al—Si—O layer, or
an Al—Si—N layer.

Furthermore, it is conceivable that a further Si interlayer is deposited between the substrate and the base coating film.

Furthermore, it can be provided that the first Si-containing layer and/or the second-containing layer are formed having a multilayer architecture.

Particularly, according to a further aspect of the present invention a method for producing a coated substrate according to the present invention can be provided, wherein the method comprises following steps:
providing a substrate having a surface to be coated,
depositing a base coating film on the surface to be coated of the substrate,
depositing a Si-containing coating film on the surface to be coated of the substrate, wherein the method used for producing the Si-containing coating comprises at least one of following process steps:
   deposition of a first Si-containing layer by using a chemical vapor deposition process (CVD process), more preferably a plasma enhanced CVD process (PECVD process),
      and/or
deposition of a second Si-containing layer by using a process combining:
   a CVD process and a cathodic arc evaporation physical vapor deposition process (arc PVD process), or
   a PECVD and an arc PVD process.

### Technical Details of the Invention

Architectural designs comprising reactively grown Si-containing top coatings embody an exciting approach to protect oxidation-prone base layers, such as binary transition metal diborides, against oxidation.

In order to better explain the present invention some examples will be explained below in more detail.

### EXAMPLES

Mixed reactively/arc evaporated Al—Si—N, Al—Si—O, and Si—O top coatings were applied on sputter-deposited tungsten diboride, titanium diboride and hafnium diboride coating films. In these examples following chemical element compositions were measured:
Tungsten diboride coating film having chemical element composition WB_{1.9},
Titanium diboride coating film having chemical element composition TiB_{2.7}, and
Hafnium diboride coating film having chemical element composition HfB_{2.4.}

The expression “mixed reactively/arc evaporated Al—Si—N, Al—Si—O”, was used for indicating that for the deposition of the Al—Si—N and Al—Si—O top coatings within the coating chamber, reactive arc evaporation physical vapor deposition processes were used in which the material used for the formation of the coatings is obtained simultaneously from vapor produced by arc evaporation of a target within the coating chamber and from reactive gases introduced into the coating chamber. More concretely in the present examples, for the deposition of Al—Si—N and Al—Si—O, an aluminum target (Al target) was arc evaporated within the coating chamber for supplying the necessary amount of Al, and at the same time respective reactive gases were introduced into the coating chamber for supplying the necessary amount of silicon (Si), oxygen (O) and nitrogen (N) and the coating material resulted from the reaction of these elements. More exactly silane and nitrogen gas flows were introduced as reactive gases for the synthesis of Al—Si—N, and silane and oxygen gas flows were introduced as reactive gases for the synthesis of Al—Si—O. Therefore, the coatings produced by using such reactive arc evaporation PVD (physical vapor deposition) processes were called in the present description “mixed reactively/arc evaporated coatings”. In the case of the deposition of Si—O, only reactive gases (silane and oxygen gas flows) were introduced in the coatings chamber and a plasma was used for providing the required energy for supporting the necessary reactions for the synthesis of Si—O. Therefore, the known term PECVD was used for referring for this kind of coating processes.

The chemical element composition measurements were carried out by using the method ICP-OES, further details are explained in the description below.

A Si layer was applied in each case between the Si- or Al/Si-containing top coating and the respective transition metal diboride coating film (hereafter also called under coating layer, because it is deposited in each case under the Si- or Al/Si-containing top coating). Hence, in these examples a Si layer was deposited in each case between the respective WB_{1.9}, TiB_{2.7}, and HfB_{2.4} film.

and the Si- or Al/Si-containing top coatings.

The Si layer was applied in particular on the examples the WB_{1.9}, TiB_{2.7}, and HfB_{2.4} films, respectively, to protect the respective underlying diboride film against oxidation during the deposition of the inventive Si-containing or Al/Si-containing top coatings.

In the present examples of the invention oxide-based top layers of the type of aluminum silicon oxide and silicon oxide were used as Al/Si-containing and as Si-containing top coatings, respectively (Al—Si—O and Si—O).

The above-mentioned coatings were tested in oxidation treatments up to 1400 °C and it was found that both the Al—Si—O and the Si—O top coatings provided outstanding oxidation resistance, in particular when these top coatings were applied on top of the TiB_{2.7} and HfB_{2.4} films, respectively.

During isothermal annealing in ambient air at 1200 °C for 30 h, these coating architectures reveal no sign of delamination or oxygen diffusion inward the respective under coating layer, in other words, no oxygen diffusion inward the coating beyond the Si adhesion layer was observed (in direction from top coating to the respective under coating layers).

In the case of using HfB_{2.4} as under layer, the Si—O based top layer (or also simply called Si—O top coating) exhibited a fully dense SiO₂ based scaling and no further indications of any degradations were observed, such as recrystallization of the HfB_{2.4} under layer. Similar results were observed for the example in which the HfB_{2.4} under layer and the Al—Si—O based top layer (or also simply called Al—Si—O top coating). In both cases a Si layer was deposited (used as interlayer) in between.

In this manner, the present invention allowed protection of the transition metal diborides films shown in that the Al—Si—O and Si—O based top coatings impressively withstood the challenging oxidative environment at 1200 °C and consequently the underlying diboride films remained unaffected by oxygen.

### Description of Experimental Details—Focus on Examples for Illustration of the Present Invention

The Examples described in the present description and corresponding experimental details are used just for facilitating illustration of the present invention. These Examples and experimental details are described for showing at least one way to produce the inventive coatings or inventive coated substrates according to the present invention. Therefore, these experimental details should not be understood as being the only way to produce the inventive coatings or inventive coated substrates according to the present invention. Hence, these experimental details should not be understood as a limitation of the present invention.

The coatings described below as illustration of the present invention were deposited on single-crystalline (11̅02, 10×10×0.53 mm) and polycrystalline Al₂O₃ (20×7×0.38 mm³) substrates for facilitating the conduction of the tests used for the determination of the coating properties described in the present description.

However, the use of the above-mentioned substrates should not be understood as a limitation of the present invention but just as the substrates selected for the conduction of specific tests for determination of specific properties—

The substrates were ultrasonically cleaned in acetone and ethanol for 10 min before coating deposition. This cleaning process should also not be understood as a limitation of the present invention. Any cleaning process known to be used for cleaning of substrates before deposition of a coating on a surface of the substrate can be used.

The deposition process (i.e. the coating process) in these examples was conducted in two steps:
1^{st} step: Deposition of a base layer (also called under coating layer or under layer or underlying coating or underlaying layer or underlaying coating layer).
2^{nd} step: Deposition of a top layer (also called top coating layer or top layer).

The 1^{st} step of the deposition process in these Examples was carried out by starting with synthesizing the base layer, which was in each case a TM-diboride (transition metal diboride) film (also called thin film because its thickness is in an order of magnitude of nanometers or micrometers ranges).

Afterwards the 2^{nd} step of the deposition process was conducted, in which in each case a Si-containing or Al/Si-containing top coating was deposited atop the corresponding TM-diboride film (also called Si-based or Al/Si-based protective layer on top).

### Details about the Deposition of TM Diboride (Also Abbreviated as TMB_{2+z} or TMB₂ in the Present Description)

In the here described examples used for illustration of the technical effect of the present invention, which are not intended to be a limitation of the present invention, the synthesis of the TM-diboride thin films (WB₂, TiB₂, HfB₂) was performed in a laboratory-scale magnetron sputtering system applying 3-inch compound targets manufactured by the company Plansee (Plansee Composite Materials GmbH [29]). In each case, for the deposition of the respective transition metal diboride coating layer, targets made from the same transition metal diboride were used as material source. Thus, tungsten diboride targets, titanium diboride targets and hafnium diboride targets were used for the deposition of the tungsten diboride coating layer, titanium diboride coating layer and hafnium diboride coating layer, respectively. The targets were powered in direct current mode (DCMS) using Argon (purity of 99.999%, provided by Linde Gas GmbH) as a working gas. A base pressure below 3×10⁻⁴ Pa was ensured before all depositions. Prior to the coating processes, the substrates were additionally cleaned through an Ar-ion etching (argon ion etching step for 10 min, conducted at a total Ar pressure of 5 Pa and a substrate bias potential of −800 V. The target surface was further sputter-cleaned during the final 3 min of the Ar-etching sequence with a shutter placed between the target and substrate. The coating process was operated at a target-to-substrate distance of 90 mm at a constant substrate temperature of 550 °C. The substrates were placed in a rotating substrate holder (0.25 Hz) with a constant substrate bias potential of −40 V. The deposition pressure was kept constant at 0.56 Pa. The coating times varied depending on the material system to obtain uniformly 2 μm thick coatings, being 80 min for WB₂ and HfB₂ thin films, and 180 min for the TiB₂.

### Details About the Top Layer Deposition

In the here described examples used for illustration of the technical effect of the present invention, which are not intended to be a limitation of the present invention, the following step, i.e. the deposition of the Si-containing or Al/Si-containing top layer was carried out in an industrial-scale Oerlikon Balzers INNOVA deposition system. This deposition system was used for depositing three kinds of Si-based or Al/Si-based top layers (Al—Si—N, Al—Si—O, and Si—O) onto the TM-diboride thin films described above (WB₂, TiB₂, HfB₂).

In these examples the top coatings were deposited by maintaining a base pressure below 0.05 Pa and the substrates were rotated using a two-fold rotating carousel. The chamber was heated until attaining a substrate temperature of 450 °C for the deposition of the silicon oxide (Si—O) and aluminum silicon nitride (Al—Si—N) coatings, whereas for the aluminum silicon oxide (Al—Si—O) top coating the chamber was heated until attaining a substrate temperature of 550 °C.

The term “base pressure” used above refers to the pressure that was measured before starting the deposition process and before introducing any gas flows into the coating chamber. It provides information about the quality of the vacuum in the chamber before synthesizing the coatings.

In each case in these examples, to protect the TM-diboride thin films from immediate oxidation during the reactive deposition of the Al—Si—O and Si—O coatings as well as to achieve enhanced adhesion on the interface, a Si interlayer was deposited between the transition metal diboride under layer and the top coating. The Si interlayer was produced having a thickness of about 0.45 μm. This thickness of 0.45 μm of the Si layer should however not be considered as a limitation of the present invention but only as an example of a possible thickness that works.

The Si interlayer in these examples was produced by using a reactive deposition process based on the Oerlikon Balzers central beam technology (average current of 120 A), using a mixture of silane and argon gas (90 sccm SiH₄, 80 sccm Ar, both with a purity of 99.9% from Linde Gas GmbH). A bipolar substrate bias with a potential of ±40 V was utilized during deposition of the coating (i.e. the substrate bias value is during coating deposition periodically alternated between the negative value −40 V and the positive value +40 V). It is of course only one way for producing such Si layers and not a limitation. It means, it is possible to use different kind of processes as well as coating conditions implying different deposition parameters for the deposition of such Si layers as interlayer or intermediate layer.

For the deposition of the Si—O layer as top coating in these examples, the same kind of process and almost the same deposition conditions were used as for the deposition of the Si interlayer as described above, however the difference was that an oxygen flow was additionally introduced, more exactly 180 sccm of O₂ were additionally introduced.

For the deposition of the respective Al—Si—O top coatings and Al—Si—N top coatings in each case in these examples, a reactive arc evaporation process was used, without using the central beam technology used for the deposition of the Si layer and the Si—O layer described above. Thus, for the deposition of the Al—Si—O and Al—Si—N top coatings, respectively, an Al target (with purity of 99.9%, manufactured by Plansee Composite Materials GmbH) was used. The Al target was operated as cathode in an arc evaporation process with a source current of 140 A. Si (silicon) was provided by introducing a SiH₄ gas flow (silane gas flow), more exactly a SiH₄ gas flow at a flow rate of 50 sccm.

For the formation of the Al—Si—O top layers, a bipolar substrate bias voltage (also called substrate bias potential) of +60 V was applied at the substrates to be coated during the deposition of Al—Si—O, and an oxygen gas flow of 180 sccm was also introduced for providing the necessary oxygen to form the Al—Si—O coating material.

For the formation of the Al—Si—N top layers, Al—Si—N was synthesized by applying a substrate bipolar bias potential of ±40 V, and a nitrogen gas flow was introduced by maintaining a constant total pressure of 2 Pa.

### Details about the Characterization of the Coatings Described as Examples

The chemical composition of the TM-diboride films was determined by using inductively coupled plasma optical emission spectroscopy (ICP-EOS) intermediately between the coating processes. Details on the procedure can be found in the scientific article “Influence of Si on the oxidation behavior of TM-Si—B_{2±z} coatings (TM=Ti, Cr, Hf, Ta, W)” in Surf. Coat. Technol. 434(2022) 128178, by T. Glechner et al.

Cross-sectional characterization of the as deposited coating architecture and growth morphology was performed by scanning electron microscope (SEM) imaging using a Zeiss Sigma 500 VO. Investigations of the thin films after oxidation treatments were conducted using a FEI Quanta 200 FEGSEM system. The fracture cross-sections of all samples were investigated with an acceleration voltage of 5.0 kV to minimize charge build-up.

Structural information as well as the phase composition of as deposited and oxidation treated samples was obtained by X-ray diffraction (XRD) using a Panalytical X'Pert Pro MPD system operated in Bragg-Brentano geometry with Cu—K_{α} radiation (wavelength λ=1.5418 Å).

To investigate the high-temperature behavior, dynamic oxidation tests in a mixture of synthetic air (50 ml/min) and helium protective gas (20 ml/min) were carried out in a combined DSC/TGA system (Netzsch STA 449 F1) equipped with a Rhodium furnace (TGA signals were processed only). The dynamic oxidation tests were performed from room temperature up to 1400 °C with a heating rate of 10 °C/min. Before each sample measurement, a baseline measurement was carried out with an empty crucible under equivalent conditions. The TGA data was recorded from coatings synthesized on pre-weighed polycrystalline Al₂O₃ substrates, which allowed for a precise measurement of the coating-only mass after the deposition process. Since the substrate material is inert in the investigated temperature range, any mass-change is directly related to oxidation/spallation/evaporation effects of the actual thin film material.

Additional long-term oxidation experiments up to 30 h were conducted in a conventional box furnace in ambient air at 1200 °C. Before these isothermal experiments, the adhesion between the TM-diboride and the protective layer (i.e. Si or Al/Si-containing top coating) was increased through vacuum annealing at 800 °C for 30 min. The annealing was conducted in a CENTORR VI LF Series vacuum furnace at a heating rate of 20 °C/min and a base pressure below 1*10⁻³ Pa.

The vacuum annealing process was used because vacuum annealing can enable metallurgical bonding between the substrate and the coating and provide stress relief. Adhesion can be therefore improved through diffusion processes and possibly the formation of new chemical compounds at the interface.

This step (vacuum annealing) is not essential for attaining the benefits of present invention but can be included in preferred embodiments of the present invention.

In other words, the very good protection of oxidation-prone borides is attained by the present invention also without using the vacuum annealing step.

However, in the preferred embodiment in which the vacuum annealing step is used, any possibility of spalling off of the top coatings (Si- or Al/Si-containing top coatings) can be further reduced depending on the oxidation-prone layer (underlayer) and substrate used.

Finally, transmission electron microscope (TEM) studies of two selected samples ((one of the two selected samples is a sample coated with Hf_{2.4}+Si+Al—Si—O and the other one is coated with Hf_{2.4}+Si+Si—O) were performed to investigate the oxide-scale formation and coating architecture after long-term annealing using a FEI TECNAI F20 (S)TEM system (operated at 200 kV acceleration voltage). Selected area electron diffraction (SAED) images were taken for qualitative structural analysis. The TEM lamellas were prepared via a standardized focused ion beam (FIB) lift out procedure. The local chemical composition was further determined by electron energy loss spectroscopy (EELS). The EELS data were analyzed using the Digital Micrograph software package (Gatan Microscopy Suite, version 3.x).

### Results of the Characterization and Analysis

FIGS. 1 to 10 will be used for explaining the results and analysis of the results in more detail:

In FIG. 1 all possible architectural designs are shown. In FIG. 1a) it is shown the architectural design comprising a substrate 1 coated with a transition metal diboride underlayer 100, a Si-containing or Al/Si-containing top coating layer 220, and an intermediate layer 210 for improving adhesion of the top coating to the underlayer 100 and avoiding oxidation of the underlayer 100 during deposition of the top coating layer 220. In FIG. 1b) it is shown the architectural design comprising a substrate 1 coated with a Si-containing or Al/Si-containing top coating layer 220 and an intermediate layer 210 for improving adhesion of the top coating to the surface to be coated of the substrate 1 and avoiding oxidation of the substrate to be coated of the substrate 1 during deposition of the top coating layer 220. In FIG. 1c) it is shown the architectural design comprising a substrate 1 coated with a transition metal diboride underlayer 100 and a Si-containing or Al/Si-containing top coating layer 220, without any intermediate layer 210 for improving adhesion of the top coating to the underlayer 100 and avoiding oxidation of the underlayer 100 during deposition of the top coating layer 220. The architectural design shown in FIG. 1a) was used in the cases in which the three different TM-diborides mentioned above (with TM=W, Ti, and Hf, respectively, i.e. WB₂, TiB₂ and HfB₂, respectively) were combined with the respective above mentioned protective top layers (Al—Si—N, Al—Si—O, and Si—O, respectively) and the intermediate layer was deposited in between, so that in summary following combination were produced WB₂+Si+Al—Si—N, WB₂+Si+Al—Si—O, WB₂+Si+Si—O, TiB₂+Si+Al—Si—N, TiB₂+Si+Al—Si—O, TiB₂+Si+Si—O, HfB₂+Si+Al—Si—N, HfB₂+Si+Al—Si—O, HfB₂+Si+Si—O. The architectural design shown in FIG. 1b) was used in the cases in which no TM-diborides were deposited but only the respective above mentioned protective top layers (Al—Si—N, Al—Si—O, and Si—O, respectively) and the intermediate layer was in each case deposited in between (between substrate and protective top layer), so that in summary following combination were produced Si+Al—Si—N, Si+Al—Si—O, Si+Si—O, Si+Al—Si—N, Si+Al—Si—O, Si+Si—O. The architectural design shown in FIG. 1c) was used in the cases in which the three different TM-diborides mentioned above (with TM=W, Ti, and Hf, respectively, i.e. WB₂, TiB₂ and HfB₂, respectively) were combined with the respective above mentioned protective top layers (Al—Si—N, Al—Si—O, and Si—O, respectively) without any intermediate layer in between, so that in summary following combination were produced WB₂+Al—Si—N, WB₂+Al—Si—O, WB₂+Si—O, TiB₂+Al—Si—N, TiB₂+Al—Si—O, TiB₂+Si—O, HfB₂+Al—Si—N, HfB₂+Al—Si—O, HfB₂+Si—O. The following sections contain a comprehensive analysis of some of the sample configurations analyzed with respect to their growth morphology and oxidation resistance in high-temperature oxidative environments.

### FIGURE CAPTIONS

FIG. 1. Architectural design. FIG. 1a) Architectural design preserving TMB_{2±z} coatings against high-temperature oxidation by introducing different protective top layers and Si interlayer. FIG. 1b) Architectural design preserving substrate surface against high-temperature oxidation by introducing different protective top layers and Si interlayer. FIG. 1c) Architectural design preserving TMB_{2±z} coatings against high-temperature oxidation by introducing different protective top layers without Si interlayer. Results are shown for the cases in which the Si interlayer was deposited before depositing the Al—Si—O and Si—O top layers and the case in which no Si interlayer was deposited before depositing the Al—Si—N top layer.

FIG. 2. SEM fracture cross-sections of the as-deposited coatings on single-crystalline Al₂O₃ substrates. The upper image row depicts the WB_{1.9}-based thin films with an (a) Al—Si—N, (b) Al—Si—O, and (c) Si—O protective top layer. The center and bottom image rows display the same top layer sequence for (d-f) TiB_{2.7}- and (g-i) HfB_{2.4}-bases thin films, respectively. An additional Si interlayer (as exemplarily marked and indicated with lines in (b)) is present for all Al—Si—O and Si—O top layers (see lines indicating the Si interlayer also in (c), (e), (f), (h), and (i)) to prevent the TM-diboride from oxidation during the deposition process.

FIG. 3. X-ray diffractograms of all samples in the as-deposited state (after deposition process and before any annealing treatment steps) with (a) WB_{1.9} (see hexagons indicating α-structure), (b) TiB_{2.7} (see hexagons indicating α-structure), or (c) HfB_{2.4} (see hexagons indicating α-structure) coating as base layer. Each subfigure is arranged from bottom to top, starting with the TM-diboride coating film (WB_{1.9} in (a), TiB_{2.7} in (b) and HfB_{2.4} in (c), respectively) followed in each case by the X-ray analysis of the films deposited above in each sample configuration, i.e. with additional Al—Si—N, or Si interlayer+Al—Si—O, or Si interlayer+Si—O top coating. All measurements were performed on coated polycrystalline Al₂O₃ substrates (see inverted triangles) in Bragg-Brentano geometry. Additional diffraction peaks correspond to metallic Al (see circles) and Si (see diamonds).

FIG. 4. Thermogravimetric analysis of the coating mass during dynamic oxidation up to 1400 °C in synthetic air. The data is grouped into (a) WB_{1.9}, (b) TiB_{2.7}, and (c) HfB_{2.4} based coatings, with each section containing reference data of the bare TMB₂ thin film as well as with the three top layer variants Al—Si—N, Si+Al—Si—O, and Si+Si—O, respectively.

FIG. 5. SEM fracture cross-sections of TiB_{2.7} thin films protected with Si+Al—Si—O top coatings (see (a) to (c)) as well as Si+Si—O top coatings (see (d) to (f)), where the pictures in (a) and (d) show the as-deposited state for reference (referenced as AD), and the pictures in (b) and (e) show the state after 3 h of isothermal oxidation at 1200 °C in ambient air, and the pictures in (c) and (f) show the state after 30 h of isothermal oxidation at 1200 °C in ambient air. All images were recorded on coated polycrystalline Al₂O₃ substrates.

FIG. 6. XRD diffractographs of TiB_{2.7} thin films protected with Si+Al—Si—O top coating (see Si/Al—Si—O in (a)) and with Si+Si—O top coating (see Si/Si—O in (b)). In each group ((a) and (b), respectively), the diffractograph closer to the bottom of the picture represents the as-deposited state (referenced in the FIGS. 6(a) and (b) respectively as as-dep.), followed by the data recorded after 3 h (referenced in the FIGS. 6(a) and (b) respectively as 3 h ox.), and 30 h (referenced in the FIGS. 6(a) and (b) respectively as 3 h ox.) of isothermal oxidation at 1200 °C in ambient air, respectively. The data was collected from coated polycrystalline Al₂O₃ substrates (see inverted triangles). The following standardized reference patterns are included: hexagonal TiB₂ (see dark hexagons, α-structure), cubic Al (see circles), cubic Si (see light grey diamonds), orthorhombic 3Al₂O₃.2SiO₂ (see half-filled, white/light grey diamonds), tetragonal TiO₂ (see cubes), tetragonal SiO₂ (see dark grey diamonds) and hexagonal SiO₂ (light grey not-filled hexagons).

FIG. 7. SEM fracture cross-sections of HfB_{2.4} thin films protected with Si+Al—Si—O top coatings (see Si/Al—Si—O in FIGS. 7(a) to (c)) and protected with Si+Si—O top coatings (see Si/Si—O in FIGS. 7(d) to (f)), where the pictures in (a) and (d) show the as-deposited state for reference (referenced as AD), and the pictures in (b) and (e) show the state after 3 h of isothermal oxidation at 1200 °C in ambient air, and the pictures in (c) and (f) show the state after 30 h of isothermal oxidation at 1200 °C in ambient air. All images were recorded on coated polycrystalline Al₂O₃ substrates.

FIG. 8. XRD diffractographs of HfB_{2.4} thin films protected with Si+Al—Si—O top coating shown in (a) (see HfB_{2.4}+Si/Al—Si—O in (a)) and protected with Si+Si—O top coating shown in (b) (see HfB_{2.4}+Si/Si—O in (b)). In each group, the diffractograph closer to the bottom of each picture represents the as-deposited state (referenced as as-dep.), followed by the data recorded after 3 h (referenced as 3 h ox.), and 30 h (referenced as 30 h ox.) of isothermal oxidation at 1200 °C in ambient air, respectively. The data was collected from coated polycrystalline Al₂O₃ substrates (see inverted triangles). The following standardized reference patterns are included: hexagonal HfB₂ (see dark hexagons indicating α-structure), cubic Al (see circles), cubic Si (see light grey diamonds), orthorhombic 3Al₂O₃.2SiO₂ (see half-filled, white/light grey diamonds), monoclinic HfO₂ (see cubes), tetragonal SiO₂ (see dark diamonds) and hexagonal SiO₂ (see light grey, not-filled hexagons).

FIG. 9. TEM analysis of the oxidized HfB_{2.4} thin film protected with the Si interlayer and the Al—Si—O top coating. The sample was annealed in ambient air at 1200 °C for 30 h. (a) shows a bright field image of the samples' cross section: On the bottom is the polycrystalline Al₂O₃ substrate, in the middle the HfB_{2.4} layer, above that the Si interlayer and the subsequent Al—Si—O protective top coating. The arrow in (a) represents the direction of the EELS line scan shown in (b).

FIG. 10. TEM analysis of the oxidized HfB_{2.4} thin film protected with the Si interlayer and the Si—O top coating. The sample was annealed in ambient air at 1200 °C for 30 h. (a) shows a bright field image of the samples' cross-section: On the bottom is the polycrystalline Al₂O₃ substrate, in the middle the HfB_{2.4} layer, above that the Si interlayer and the subsequent Si—O protective top coating. The arrow in (a) represents the direction of the EELS line scan shown in (b).

FIG. 11. Schematic drawing of a preferred embodiment of coated substrates according to the present invention, in which the inventive Si-containing top coating 200 (comprising 210 and 220) is applied directly on the substrate surface to be protected and the substrate 1 or at least the surface to be coated of the substrate 1 comprises TM diborides or is made of TM diborides (i.e. substrate comprises TMB_{2±z} or is made of TMB_{2±z}).

FIG. 12. Schematic drawing of a preferred embodiment of coated substrates according to the present invention, in which between the inventive Si-containing top coating 200 (comprising 210 and 220) and the substrate surface to be protected one or more further coatings layers 100 are applied, wherein the one or more coating layers 100 comprise TM diborides or are made of TM diborides (i.e. one or more layers comprising TMB_{2±z} or is made of TMB₂₊₂).

FIG. 13. Schematic drawing of a preferred embodiment of coated substrates in which a Si interlayer is deposited between the substrate and the TMB_{2±z} film for further increasing adhesion of the TMB_{2±z} film to the substrate.

FIG. 14. SEM cross-section of the schematically showed coated sample in FIG. 13, in which the TMB_{2±z} film is HfB₂ and the substrate is a SiC substrate.

FIG. 15. XRD diffractographs of a HfB₂ thin film deposited on a SiC substrate, the HfB₂ thin film protected with SiO₂, and the coating comprising a Si interlayer between the SiC substrate and the HfB₂ film as well as a Si interlayer between the HfB₂ film and the SiO₂ layer in as deposited state (same coated sample as shown in FIG. 14).

FIG. 16. XRD diffractographs of the sampe coated sample shown in FIG. 14 but after vaccum annealing step.

FIG. 17. XRD diffractographs of the sampe coated sample shown in FIG. 14 but after vaccum annealing step and isothermal oxidation test at 1200 °C for 3 hours.

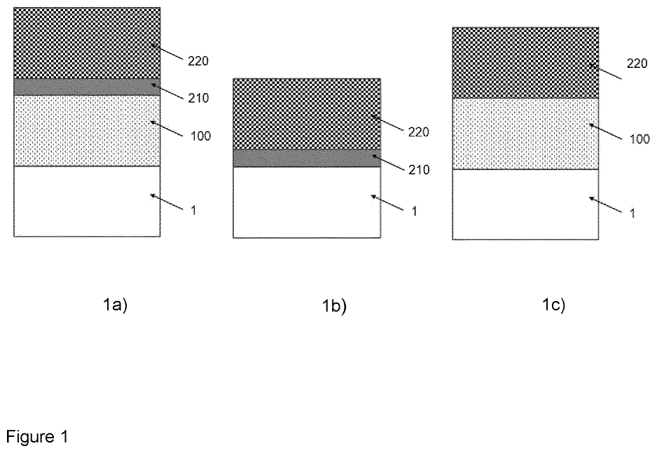

### Chemical Composition & Growth Morphology

The chemical composition of the TM-diborides was determined by ICP-OES, revealing a slight boron deficiency for the WB_{1.9} layer, while both the TiB_{2.7} and HfB_{2.4} thin films contain excess boron. Hence, it can be expected that especially the latter two variants exhibit boron-enriched grain boundary sites—typically susceptible for B₂O₃ volatilization.

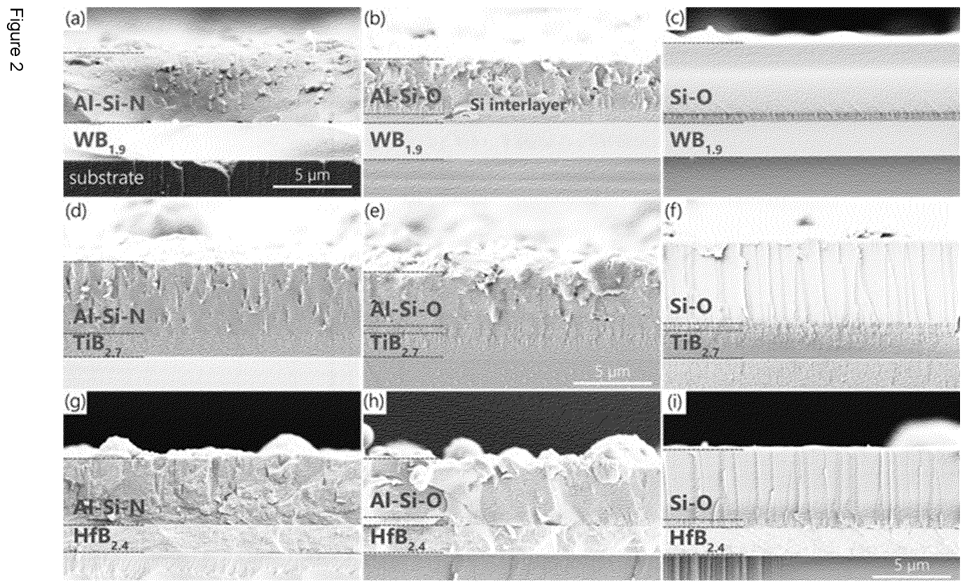

In FIG. 2 the SEM fracture cross-sections of all coating configurations are shown in the as-deposited state. The layered structure is indicated with dashed lines on the left side of each image as a guide to the eye. The polycrystalline Al₂O₃ substrate is followed by the TM-diboride layer (WB_{1.9} in FIGS. 2(a) to (c), TiB_{2.7} in FIGS. 2(d) to (f), and HfB_{2.4} in FIGS. 2(g) to (i)), a Si interlayer (only present when the Al—Si—O and the Si—O top layers were deposited) and respectively as protective surface layers the top layers Al—Si—N in (a), (d), and (g) (see left column of the FIG. 2), Al—Si—O in (b), (e), and (h) (see center column of the FIG. 2), and Si—O in (c), (f), and (i) (see right column of the FIG. 2).

The TMB₂ coatings, more exactly the TMB_{2+z} coatings or TMB_{2+z} coating layers or TMB_{2+z} coating films described in the present Examples, TiB_{2.7} (TMB_{2+z} with TM=Ti and z=0.7), HfB_{2.4}(TMB_{2+z} with TM=Hf and z=0.4), and WB_{1.9}(TMB_{2+z} with TM=W and z=−0.1), show a dense and more or less featureless morphology. However, these two features (dense and more or less featureless) related to the morphology of these TMB_{2+z} coatings must not be considered essential features of this kind of coating materials for the present invention.

The term “dense morphology” is used in the present description for indicating that the morphology observed in SEM images does not exhibit a high number of pores.

The term “more or less featureless morphology” is used in the present description for indicating that a partially featureless (i.e. partially amorphous) or mainly featureless (i.e. mainly amorphous) morphology was detected in SEM images and XRD diffractograms of the examined TMB_{2+z} coatings described as Examples. This is however not an essential feature.

The expression “featureless morphology” detected in SEM images is used in the cases in which the examined morphology has the appearance of the morphology of a glass material in SEM images. A such morphology is also called amorph or glassy-like in SEM images because of its likeness to the morphology of glass materials.

The expression “featureless morphology” detected in XRD diffractograms is used in the cases in which the material is amorphous according to the XRD examinations, because no peaks indicating crystalline structures can be detected in the XRD diffractograms.

TiB_{2.7} exhibits slight indications for a columnar morphology in topmost regions.

The measured average thickness of the TM-diboride films was determined to be respectively about 2.3 μm for the WB_{1.9} layer, 1.9 μm for the TiB_{2.7} layer, and 1.8 μm for the HfB_{2.4} layer. The measured thickness of the Si interlayer introduced for all samples with Al—Si—O and Si—O top layers was determined to be respectively in each case about 450 nm. Moreover, the measured average thickness of the different protective top layers was determined to be respectively about 4.6 μm for Al—Si—N, 3.6 μm for Al—Si—O, and 4.7 μm for Si—O. The top coatings further appear in the SEM images as homogenous and dense without any texture clearly detected in XRD diffractograms on the TM-diboride thin films described in the present Examples. However, in contrast to the TiB_{2.7} and HfB_{2.4} thin films, more pores can be seen in the SEM images at the interface between the Al—Si—N top coat and the underlying WB_{1.9} film, indicating poor interface adhesion. In addition, due to the arc evaporation process from elemental aluminum targets, both the Al—Si—N and Al—Si—O coatings contain metallic macro particles of aluminum coming from the aluminum targets which contribute to increased surface roughness.

### Phase Formation

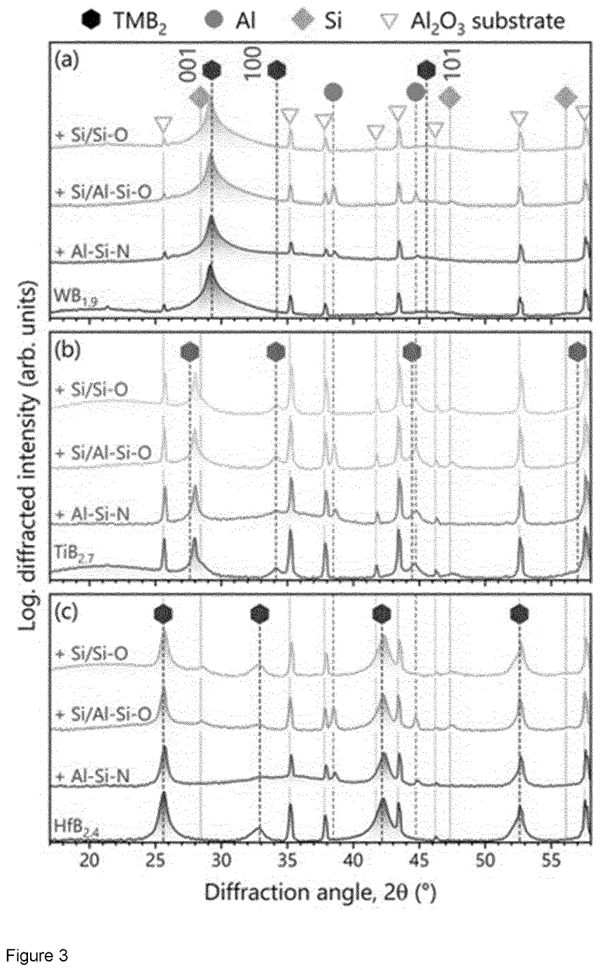

The phase formation of each layer during the successive deposition stages was investigated by X-ray diffraction in Bragg-Brentano geometry, as presented in FIG. 3. The diffractograms are grouped according to the TM-diboride base layer, with the data in FIG. 3(a) corresponding to WB_{1.9}, in FIG. 3(b) corresponding to TiB_{2.7}, and in FIG. 3(c) corresponding to HfB_{2.4}, respectively. The X-ray spectrums in each subfigure (a), (b), and (c), are arranged from bottom to top of the corresponding subfigure, starting with the bare TM-diboride film (bare TM-diboride means in this context without additional coating layers atop of the TM diboride film), followed by the samples having an additional top coating of Al—Si—N, or of Si/Al—Si—O (Si interlayer plus Al—Si—O top coating), or of Si/Si—O (Si interlayer plus Si—O). All TM-diborides were synthesized as single-phased, α-TMB₂ structured (i.e. having same/similar crystal structure like aluminum diboride, hence also called AlB₂ crystal structure or AlB₂ prototype) thin films. In particular, WB_{1.9} and TiB_{2.7} exhibit a clearly preferred (001) growth orientation. Contrary, the HfB_{2.4} containing samples reveal a polycrystalline grain orientation. The polycrystalline grain orientation is evident from the XRD analysis. This means that there are many preferred orientations (several peaks with high intensity can be assigned to the TiHf₂ phase). Both sample configurations with the Si interlayer further contain diffraction peaks corresponding to pure Si, suggesting that the Si interlayer is indeed in a partially crystalline state.

However, the most striking observation in the diffractograms is that irrespective of the TM-diboride, all protective top layer variants were deposited in a fully X-ray amorphous state, as suggested by the lack of additional diffraction peaks. Solely two reflexes are indicative of metallic Al are observed for the samples containing Al—Si—N and Si/Al—Si—O (Si+Al—Si—O) top coatings. Following the SEM fracture cross-section in FIG. 2, these peaks can be assigned to Al-rich macro-particles formed during the arc evaporation process.

### Dynamic Oxidation

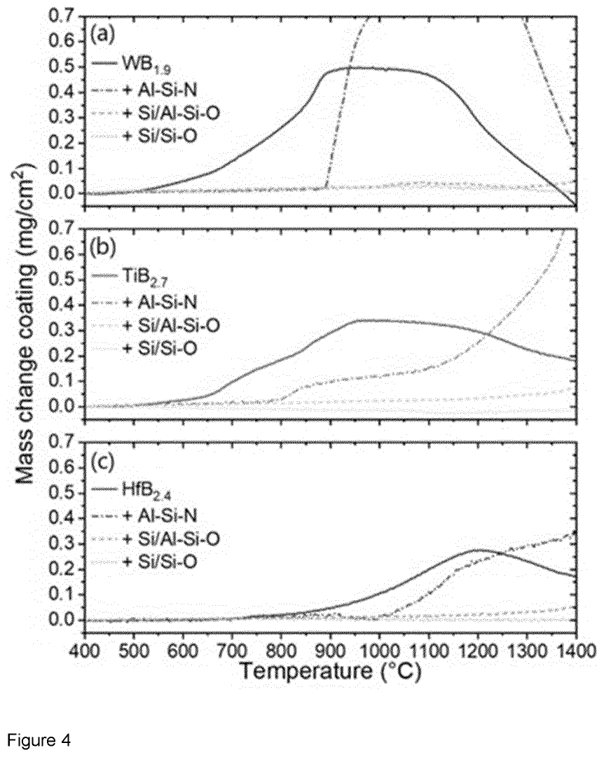

The oxidation behavior of all coating variants including the respective, bare TMB₂ thin films without protective top layer was investigated by dynamic oxidation experiments in synthetic air up to 1400 °C (10 °C/min heating rate). FIG. 4 presents the mass change of the coating material normalized to the coated area as function of the temperature. Please note, that only pre-weighted, inert substrates have been used.

The reference measurements of the bare TMB₂ thin films clearly highlight the necessity for additional measures to sustain these materials to oxygen containing environments at elevated temperatures. While WB_{1.9} and TiB_{2.7} reveal a similar oxidation onset temperature of about 500 °C (see FIGS. 4(a) and (b)), HfB_{2.4} is able to tolerate temperatures between 700 and 750 °C before noticable mass gain is recorded (see FIG. 4(c)). The data confirms that the bare diboride materials (irrespective of the stoichiometry) are incapable of forming protective oxide scales, with the coating mass increasing to a respective maxima between 900 and 1200 °C. At temperatures beyond 1200 °C all TMB₂ thin films show a decreasing mass signal, which correlates with the volatilization of B₂O₃.

Adding a protective Al—Si—N top coating to the TMB₂ thin films results in increased oxidation resistance for all samples, visible in a pronounced shift of the oxidation onset temperature to a range between 800 and 1000 °C. Interestingly, not only the oxidation onset temperature varies between the samples, also the recorded oxidation kinetics are markedly different. While the Al—Si—N coating on WB_{1.9} suffers from accelerated mass gain-even exceeding the WB_{1.9} reference data above 950 °C (see FIG. 4(a)) the identical coating on TiB_{2.7} and HfB_{2.4} allows for enhanced oxidation resistance up to ~1000 °C before continued oxide scale growth is observed (see FIGS. 4(b) and (c)). This drastic oxidation of the Al—Si—N on top of WB_{1.9} is attributed to small pores, indicating weak adhesion, as seen in the cross section in FIG. 2(a). Moreover, the Al—Si—N protected TiB_{2.7} reveals a step-wise oxidation behaviour with a stable mass plateau of ~0.10 mg/cm² between 850 and 1050 °C (see FIG. 4(b)), suggesting the temporary formation of a stable oxide scale prior to a full oxidation of the remaining coating material. The general difference in oxidation behaviour between these samples may be seen in varying growth morphologies of the Al—Si—N coating—note the absence of a uniform interlayer in the architecture—as well as from differences in thermal expansion to the base TMB₂ coatings (Thermal Expansion of Metal Diborides (MB<sub>2</sub>|M=Ti, Zr, Nb, Hf, Ta) up to 3150 C (mrs.org)). Overall, the dynamic oxidation tests involving Al—Si—N protective top layers without using any Si-interlayer did not result in the formation of a sufficient oxygen barrier above 1000 °C, hence these sample configurations were excluded from the following isothermal oxidation treatments (see Section “Isothermal oxidation” below). However, by using a Si-interlayer between the TMB_{2+z} film and the top protective coating of Al—Si—N the formation of a sufficient oxygen barrier was possible according to the present invention.

In clear contrast to the Al—Si—N coated TMB₂ samples without Si-interlayer, the top coatings applied after applying an Si-interlayer, as shown in the samples coated with Si-interlayer and both the Si/Al—Si—O and Si/Si—O coatings, respectively, enable outstanding oxidation resistance irrespective of the diboride base layer, as indicated by negligible mass gain/loss over the entire temperature range. In detail, thin films with a protective Si/Al—Si—O top layer experience a total mass gain between 0.05 to 0.07 mg/cm², particularly in the temperature range above 1150 °C. This performance is even exceeded by Si/Si—O coated samples, which reveal a maximum mass change of 0.02 mg/cm². These results suggest that both protection layer concepts provide a stable, dense scale formation that prevents a continued and fast oxygen inward diffusion towards the remaining coating material.

### Isothermal Oxidation

The long-term performance of the Si/Al—Si—O and Si/Si—O top coatings was further assessed through isothermal oxidation tests at 1200 °C for 3 and 30 h in lab-air conditions, respectively. The resulting oxide scale formation was then investigated by cross-sectional microscopy analysis and in terms of phase formation by X-ray diffraction. Prior to these tests, vacuum annealing treatments were performed for 30 min at 800 °C to improve the adhesion of the Si interlayer to the TM-diboride as well as the protective top coating as mentioned above. This pretreatment was performed to minimize any spallation of the oxide scale during sample cooling from 1200 °C. As mentioned above, this annealing treatment is optional. However, the oxidized WB_{1.9}-based samples were found to have fully delaminated from the polycrystalline Al₂O₃ substrates for both oxidation periods, indicating limited adhesion under the tested conditions and thus preventing further investigations. Consequently, the coatings comprising WB_{1.9} are excluded from the present invention. Accordingly, coatings comprising TMB_{2+z} with TM=W and z<0 as in this case in which z=−0.1 are not considered part of the invention. In general, TMB_{2+z} with z<0 (z less than cero), i.e. under stoichiometric (also called sub stoichiometric) transition metal diborides, are not part of the invention.

Concretely, by using coating systems according to the present invention, in which a Si-based interlayer is provided between the TMB_{2+z} film with 1≥z≤0, preferably 0.75≤z≥0 and the Si-containing top coating layer preferably based on at least one of Si—O, Al—Si—O or Al—Si—N (i.e. comprising at least one layer based on at least one of Si—O, Al—Si—O or Al—Si—N), a surprisingly excellent oxidation resistance was attained. Especially by using as transition metal TM=Hf and/or Ti.

This invention has been shown to be particularly advantageous for protecting substrates to be exposed to high temperatures of 1000 °C or higher, in particular carbon substrates, boron-rich substrates, substrates comprising composite materials, silicon carbides, zircon carbides, hafnium carbides, boron carbides, and/or other carbides.

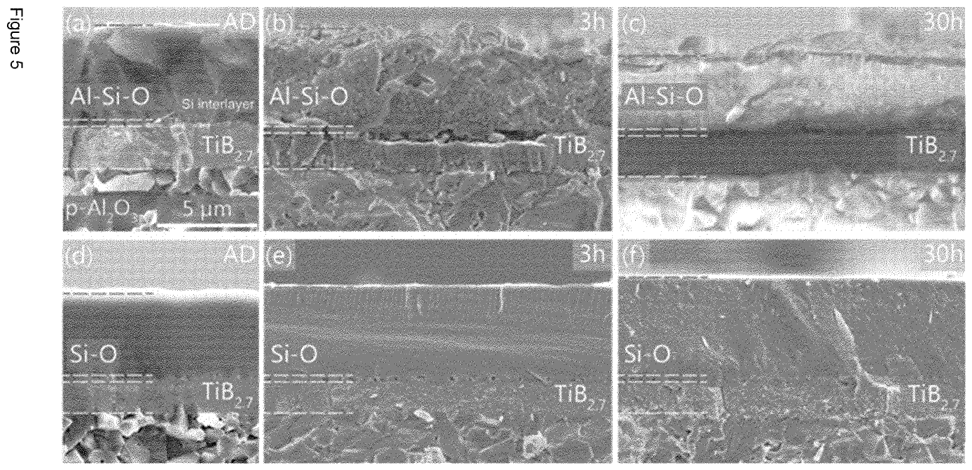

FIG. 5 displays the SEM fracture cross-sections of all oxidation-treated samples with TiB_{2.7} base layer. The upper image row (see FIGS. 5(a) to (c)) corresponds to the coating comprising titanium diboride (TiB_{2.7}) followed by Si/Al—Si—O, while the bottom image row (see FIGS. 5(d) to (f)) corresponds to the coating comprising titanium diboride (TiB_{2.7}) followed by Si/Si—O. From left-to-right the images are aligned with increasing duration of the oxidation treatment. After 3 h of isothermal oxidation (see FIGS. 5(a) and (b)), the protective Si/Al—Si—O layer exhibits a significant change in morphology. The protective coating shows increased porosity—in particular within the Si interlayer—and a pronounced increase in surface roughness when compared to the as-deposited state. The underlying TiB_{2.7} coating, however, visually remains unchanged after the first annealing treatment. Furthermore, adhesion to the polycrystalline Al₂O₃ substrate appears to be intact. After 30 h oxidation at 1200 °C (see FIG. 5(c)), the pore formation within the Si interlayer progresses, whereas porosity in the Al—Si—O top coating appears reduced.

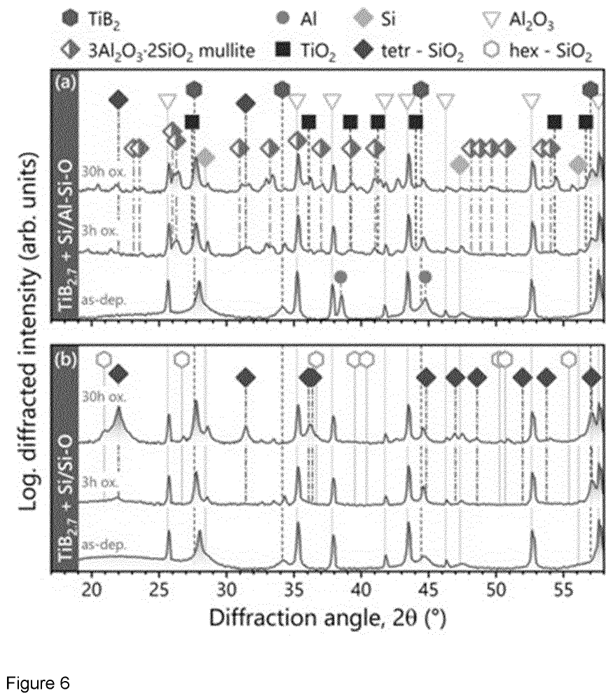

FIG. 6(a) contains the corresponding X-ray diffractograms, arranged from bottom to top with increasing oxidation time. The data recorded after 3 h already indicates the formation of several crystalline structures within the protective coating architecture. Comparison to standardized reference patterns suggests that the Al—Si—O coating crystallizes into an 3Al₂O₃.2SiO₂ mullite-based structure. In addition, the presence of both tetragonal and hexagonal SiO₂ as well as hints for a TiO₂ phase are observed. Also, the partly amorphous Si interlayer crystallizes at this temperature range. After 30 h, the intensity of all diffraction peaks including that of TiB₂ increases, suggesting continued crystallization and grain growth. Overall, the presence of the TiB₂ phase after the oxidation treatment shows the oxygen barrier capabilities of the protective layer concept.

The SEM images in FIGS. 5(d) to (f) show TiB_{2.7} coatings protected by Si/Si—O. The top coating has a dense, featureless morphology in the as-deposited state (see FIG. 5(d)), which is maintained throughout the oxidation treatment (see FIGS. 5(e)-(f)). Moreover, the coating surface remains significantly smoother than for Si/Al—Si—O coated samples after oxidation. The data further shows that after 3 and 30 h, the Si interlayer exhibits initial signs of pore formation—indicative of accelerated diffusion processes—while the TiB_{2.7} coating maintains a dense morphology throughout the full oxidation treatment with only minute indications for small pores close to the substrate interface. Overall, good adhesion between the individual layers is still recorded after 30 h at 1200 °C (see FIG. 5(f)), underlining the excellent protective character of the Si—O based top coat. The respective XRD data in FIG. 6(b) again shows the (re-)crystallization of all individual layers, with the initially amorphous Si/Si—O coating transforming into tetragonal- and hexagonal-structured SiO₂ next to the recrystallized Si interlayer after 3 and 30 h at 1200 °C, respectively.

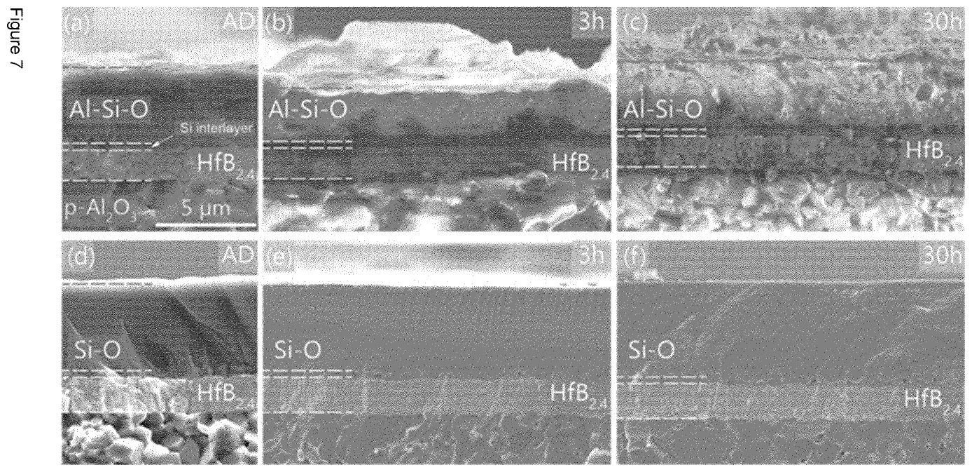

FIG. 7 shows SEM fracture cross-sections of the HfB_{2.4}-based coating architectures after identical isothermal oxidation treatments at 1200 °C for up to 30 h in ambient air. Following the arrangement of FIG. 5, all images corresponding to HfB_{2.4} protected by Si/Al—Si—O top coatings are given in FIGS. 7(a) to (c), whereas the Si/Si—O coated samples are displayed in FIGS. 7(d) to (f). Moreover, from left-to-right the images refer to increasing durations of the oxidation treatment.

After 3 h annealing at 1200 °C, HfB_{2.4} protected by Si/Al—Si—O (see FIG. 7(b)), exhibits a more textured and granular morphology throughout all layers. In addition, the top surface of the protective Al—Si—O layer shows a pronounced increase in surface roughness. After 30 h of annealing (see FIG. 7(c)) all layers obtained a globular morphology, with small pores formed throughout the HfB_{2.4} as well as the Al—Si—O coating close to the Si interlayer. Nevertheless, the initial layered structure is distinctly maintained and the layer adhesion between the polycrystalline Al₂O₃ substrate and the subsequent layers is still given.

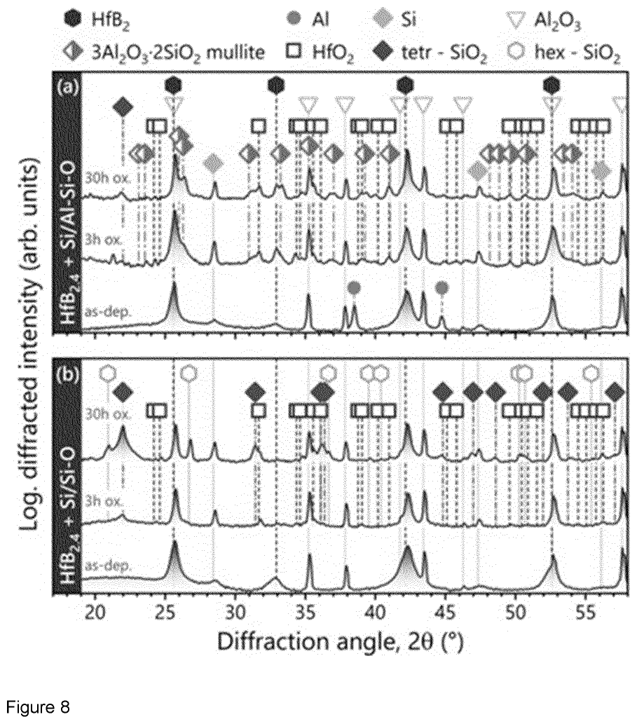

Similar to the TiB_{2.7}-based coating, the corresponding X-ray diffractograms in FIG. 8a reveal the formation of a crystalline 3Al₂O₃.2SiO₂ mullite phase after 3 and 30 h of isothermal annealing. Moreover, both the tetragonal- and hexagonal-structured variants of SiO₂ are formed next to hints for a monoclinic HfO₂ phase. Still, the hexagonal HfB_{2.4} phase is well present after the entire annealing treatment, suggesting a recrystallization due to decreasing peak-width.

The final configuration of HfB_{2.4} protected by a Si/Si—O coating is studied before and after oxidation in FIGS. 7(d) to (f). Analogous to the TiB_{2.7}-based coatings, both the Si—O and the TM-diboride layer maintain a highly dense morphology even after 30 h of annealing at 1200 °C. The porosity within the Si interlayer appears less pronounced, with excellent adhesion recorded for all layers. Interestingly, slight porosity is also observed within the HfB_{2.4} thin film close to the substrate interface.

Looking at the phase formation in FIG. 8(b), next to an intact and recrystallized HfB_{2.4} phase, again the formation of tetragonal and hexagonal SiO₂ is observed. In addition, the monoclinic HfO₂ structure appears to contribute to the excellent oxidation resistance recorded for this coating architecture.

### Scale Formation on HfB2.4 at 1200 °C

Based on the previously discussed dynamic and isothermal oxidation treatments, both the Si/Al—Si—O and Si/Si—O protective coatings showed exceptional high-temperature oxidation resistance up to 1200 °C on TiB_{2.7} and HfB_{2.4}. In particular, the HfB_{2.4} samples excelled with an intact layer structure, exceptional layer adhesion and a dense microstructure—especially within the Si interlayer—after annealing for 30 h in air at 1200 °C. Therefore, a more detailed investigation on the scale growth, chemical distribution, and microstructure was conducted on oxidized HfB_{2.4} coatings with Si/Al—Si—O and Si/Si—O protective top coatings.

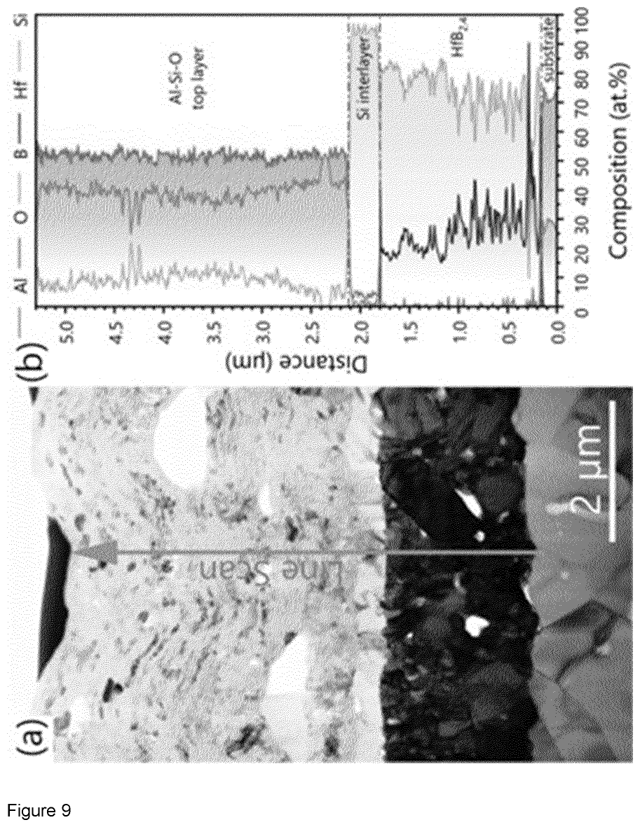

FIG. 9(a) shows a bright-field TEM micrograph of the HfB_{2.4}-Si/Al—Si—O coating architecture after 30 h isothermal oxidation at 1200 °C. As suggested by the X-ray diffraction data (see FIG. 8(a)), large globular grains within the HfB_{2.4} base layer confirm the recrystallization of the material. The image also shows a perfectly continuous adhesion of the recrystallized Si interlayer to the HfB_{2.4} and Al—Si—O coatings. Moreover, in agreement with previous SEM fracture cross-sections (see FIGS. 5(a) to (c)), the nanostructured protective top layer appears as rough and slightly porous, with large inclusions holding pure Si as determined by local EDS analysis. The observed structure is strongly connected to the crystallization of the complex orthorhombic 3Al₂O₃.2SiO₂ mullite phase from the initially amorphous coating (compare with FIG. 8(a)).

To get an insight into the diffusion processes after annealing in the high temperature regime, an EELS line scans was recorded along the full architecture. In FIG. 9(a) the position and direction of the line scan is indicated by the arrow. The line scan proves the still intact layered structure after annealing at 1200 °C: From bottom to top the substrate, the HfB_{2.4} layer, the Si interlayer, and the protective Al—Si—O layer can be clearly distinguished. Hf appears to be depleted towards the Si interlayer, where an average top concentration of about 35 at. % was found by EELS at the substrate near interface. The HfB_{2.4} layer generally appears more stoichiometric closer to the substrate. Nevertheless, the HfO₂ observed during X-ray diffraction could not be spotted in this localized analysis.

Otherwise, the line scan shows a clear demarcation of the HfB_{2.4} layer from the substrate and the adjacent, still clearly pronounced Si interlayer. Strikingly, the protective layer on top of the HfB_{2.4} and Si interlayer shows porosities within the Al₂O₃—SiO₂ matrix. These pores may also be caused because of strongly recrystallized and partly oxidized macroparticles, being not well-adherent during FIB preparation. Hardly no pores are visible in the diboride coating. Nevertheless, it can be stated that the selected coating system shows excellent oxidation resistance, tested at 1200 °C for up to 30 h. The oxygen diffusion into the diboride coating is almost negligible, as well as the Si interlayer is unaffected by oxygen. Moreover, it can be concluded that the Al—Si—O layer served as a good protective barrier against oxygen at the tested conditions.

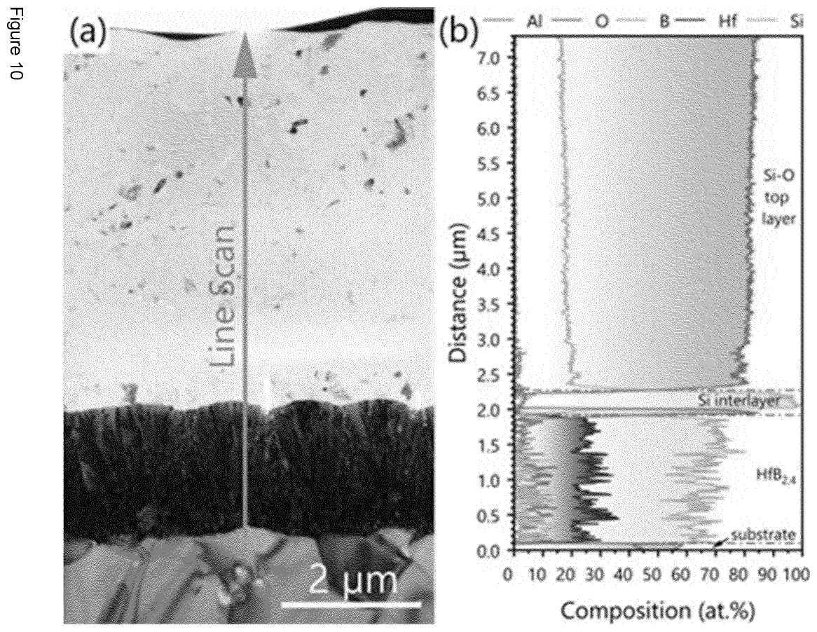

The bright-field image in FIG. 10(a) depicts the cross-sectional morphology of a HfB_{2.4} thin film protected by a Si/Si—O top coating after 30 h of oxidation treatment at 1200 °C. In contrast to the drastically recrystallized diboride coating in FIG. 9(a), the HfB_{2.4} coating maintained a columnar morphology, typical for sputter-deposited thin films. Furthermore, the entire coating architecture appears extremely dense without noticeable pores in the microstructure or between the respective sub-layers. Contrary to the Al—Si—O based top layer, the Si—O coating remained mostly amorphous with small SiO₂ crystallites embedded in the matrix.

As for the previously described sample with Al—Si—O top coating, an EELS line scan was recorded for HfB_{2.4} protected with Si—O. A Si diffusion of about 5-10 at. % into the diboride layer can be indicated. This is a highly interesting observation, as Si typically tends to separate within HfB₂ structures. The ratio between B to Hf is nearly constant over the entire thickness of the diboride layer, somewhat substoichiometric in Hf at about 25 at. %. At the interface to the Si layer, a slight decrease in Hf followed by a very narrow O peak is visible, may indicate the formation of a very thin HfO₂ layer—as suggested by the XRD in FIG. 8b. Nevertheless, this layer also impressively withstood the challenging oxidative environment at 1200 °C since the diboride film seems to be unaffected by O.

### Implication

The capability of architectural designs to protect TM diboride coatings against ultra-high temperature oxidation was attained by using Al/Si-containing top coatings (i.e. Si-containing coatings) according to the present invention. Reactively grown Si-containing top layers, in detail Al—Si—N, Al—Si—O, and Si—O, are an excellent approach providing long-term oxidation resistance for oxidation-prone binary diborides even at 1200 °C.

To validate the architectural design for a broad range of TM diborides the reactively deposited top layers (all protective top coatings are based on mixed reactive/arc evaporation processes using silane/N₂/O₂) have been applied on sputter deposited (DCMS) WB_{1.9}, TiB_{2.7}, and HfB_{2.4} films, respectively. To protect the underlying diboride against oxidation during the synthesis of the oxide based top layers (Al—Si—O and Si—O), a pure Si adhesion layer was applied. Structural analysis of the as deposited architectures revealed clearly α-structured diborides for the base layers, whereas all three top layers appear X-ray amorphous. The introduced Si adhesion layer obtains a crystalline character. During a thermo-gravimetric screening process up to 1400 °C, the Al—Si—N protective layers suffered for all diborides accelerated mass gain before 1000 °C, being far of Si—O and Al—Si—O obtaining only minor mass changes up to 1400 °C. In long term isothermal oxidation tests (1200 °C for 3 and 30 h), all WB_{1.9} based architectures were fully delaminated. However, the TiB_{2.7} and HfB_{2.4} films with Al—Si—O and Si—O on top exhibited intact, layered structures even after 30 h at 1200 °C. Detailed microstructural and chemical analysis of the HfB_{2.4} based architectures verified the outstanding oxidation resistance with no oxygen interdiffusion beyond the Si adhesion layer. Al—Si—O on top of HfB_{2.4} discloses the tendency to more pronounced diffusion processes, as the Si interlayer as well as the phase separated Al₂O₃—SiO₂ top layer obtained porosities. In addition, the underlying HfB_{2.4} was strongly recrystallized. In contrast, the fully dense Si—O protective layer exhibits no pores or further degradation indications such as recrystallization of the HfB_{2.4} base layer.

The inventions have found however that the above-mentioned adhesion problem of the Al—Si—N can be solved with the same approach as for Al—Si—O and Si—O, namely by providing a Si containing interface between the TMB_{2+z} substrate material and the corresponding protective coating (in the examples above Al—Si—O and Si—O, respectively). Hence in the case of a protective coating of Al—Si—N the problem is solved by providing a Si containing interface layer between the TMB_{2+z} substrate material and the corresponding Al—Si—N protective coating. Also, for the solution involving a Si containing interface plus Al—Si—N this strategy resulted in excellent adhesion up to 12000 °C annealing.

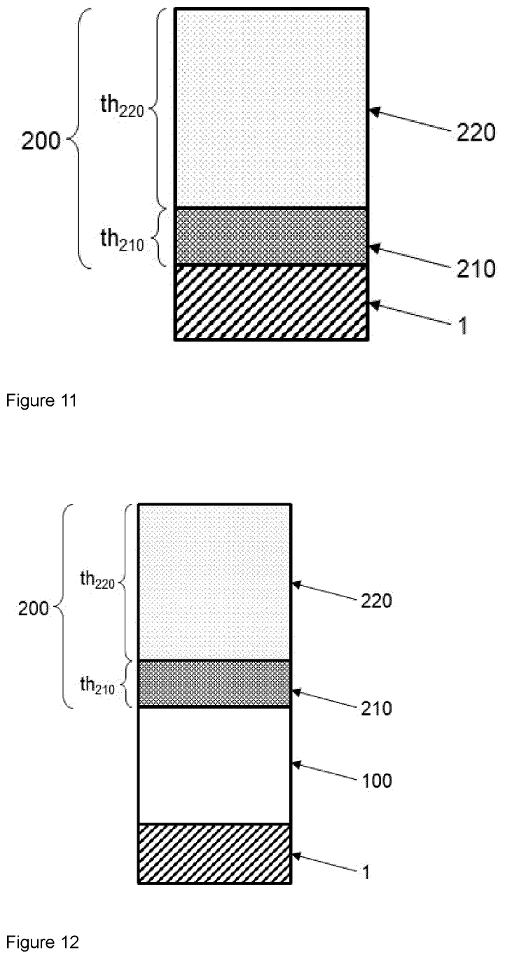

In order to explain the present invention in more detail, the FIGS. 11 and 12 will be used, which show schematically architectures of coated substrates according to the present invention.

### Additional Inventive Example by Using with SiC Substrates

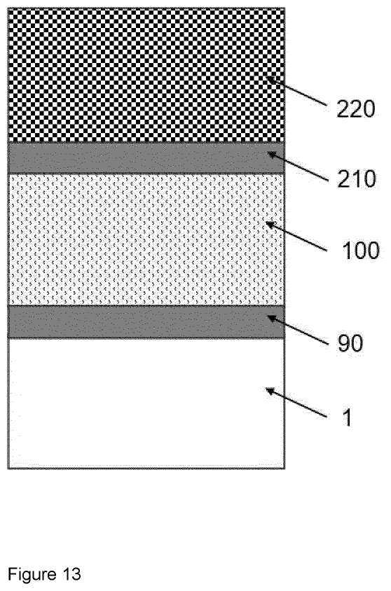

In this Example a SiC substrate (1) was coated with a TMB_{2+z} film (100) consisting of HfB₂ (i.e. with TM=Hf and z=0) and a Si—O top protective coating (220) consisting of SiO₂. A first Si interlayer (90) was deposited between the SiC substrate (1) and HfB2 layer (220) and a second Si interlayer (210) was deposited between the HfB₂ layer (100) and the SiO₂ layer (220) as schematically shown in FIG. 13.

This inventive coating system did not spall off after deposition and also not after vacuum annealing at 800 °C, and even not after isothermal oxidation at 1200 °C for 3 hours.

The use of a Si interlayer between the SiC substrate and the overlying HfB₂ layer allowed a considerably further increment of adhesion between the SiC substrate and the HfB2 layer in comparison with similar coatings but without comprising a Si interlayer between the SiC substrate and the HfB₂ layer.

In general, the Si interlayers in the present invention are silicon-containing interface layer, it means layers deposited between two surfaces (for example the silicon-containing layer can be a Si interlayer 110 placed between a surface of a TMB_{2+z} coating film 100 and a surface of a Si-containing top layer 120, or a Si interlayer 90 placed between a surface of a TMB_{2+z} coating film 100 and a surface of a substrate 1), therefore forming an interface and containing mainly silicon, or consisting essentially of silicon (can be also simply referred to as Si-containing interface layers or Si interface layers).

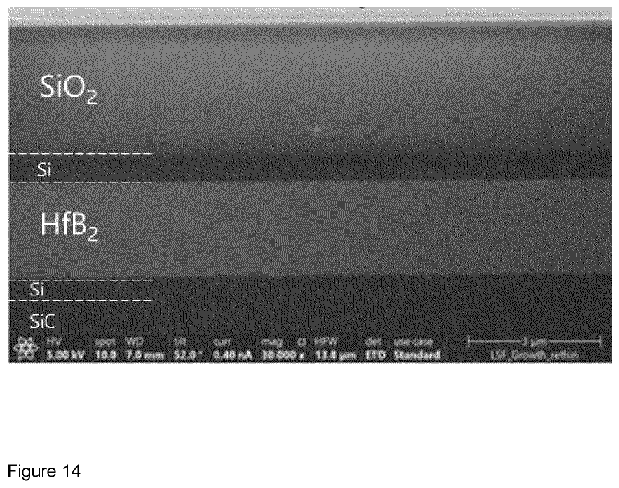

FIG. 14 shows the SEM image of the directly above-described coated sample (schematically shown in FIG. 13).

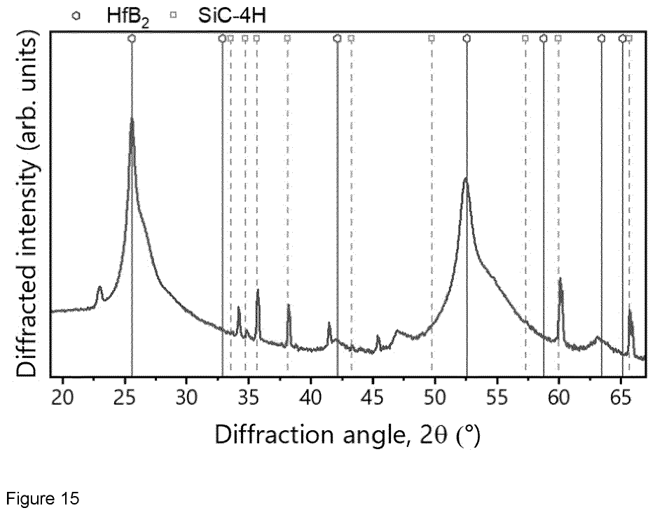

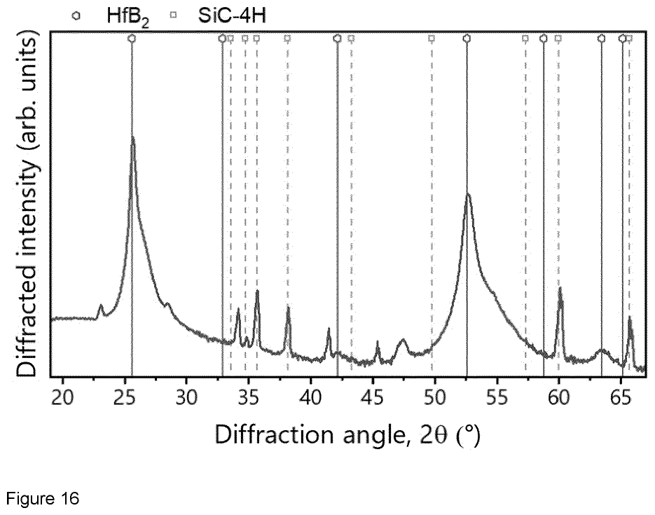

FIGS. 15, 16 and 17 show respectively the XRD diffractogram of this coated sample in as deposited state (see FIG. 15), in state after vacuum annealing step (see FIG. 16), and in state after the isothermal oxidation test at 1200 °C for 3 hours.

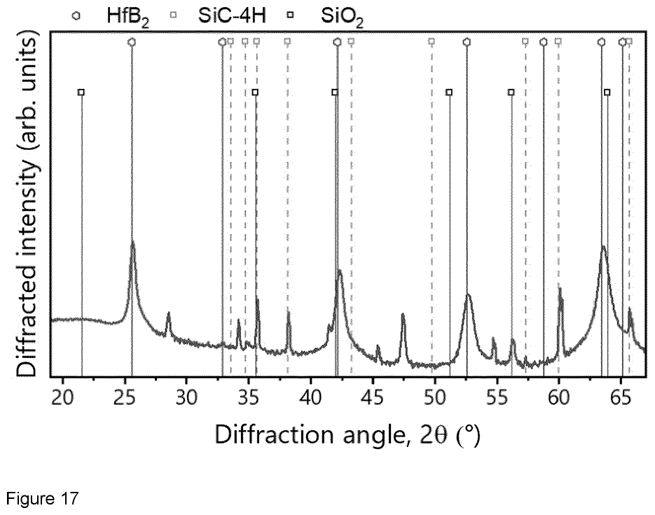

It can be observed in FIG. 17 that this coated sample showed after isothermal oxidation test no oxygen peaks and no HfO₂ peaks in the XRD, which confirms very good results concerning protection against oxidation of the HfB₂ film.

Concretely the present invention relates to a coated substrate having a coated surface being formed by a surface of a substrate (1) and at least one coating provided on said substrate surface, the at least one coating being a Si-containing coating (200), characterized in that, the Si-containing coating forming the outermost surface of said coated surface and comprising at least two Si-containing layers, a first Si-containing layer (210) and a second Si-containing layer (220), wherein the first Si-containing layer (210) being deposited closer to the substrate surface than the second Si-containing layer (220), and wherein:
the first Si-containing layer (210) being a silicon-containing interface layer, for example a Si layer, wherein the first Si-containing layer (210) having preferably a layer thickness th₂₁₀ between 50 nm and 30 μm, i.e. 30 μm≥th₂₁₀≥50 nm, and
the second Si-containing (220) layer being an oxide top layer or an oxynitride top layer or a nitride top layer, having preferably a layer thickness thicker than the first Si-containing layer thickness, i.e. th₂₂₀>th₂₁₀.

Preferably the substrate surface is formed of one or more oxidation-prone materials or is coated with one or more layers comprising oxidation-prone materials, preferably of the type of transition metal diborides (TMB_{2+z} material, where TM is one or more transition metals and B is boron and z is preferably smaller than 0.75, more preferably smaller than 0.5).

In case that no further coatings (100) are deposited between the substrate (1) and the Si-containing coating (200), then the first Si-containing layer is deposited preferably directly on the substrate surface.

According to a preferred embodiment of the present invention the inventive coated substrate comprises between the substrate surface and the Si-containing coating one or more further coatings (100), preferably at least one of said further coatings formed of an oxidation-prone material, more preferably at least one of said further coatings is made of a TMB_{2+z} material, where TM is one or more transition metals and B is boron and z is preferably not higher than 0.75 but preferably smaller than 0.75. More preferably not higher than 0.70.

Preferably the first Si-containing layer (210) is deposited atop the one or more further coatings (100).

Preferably the second Si-containing layer (220) is deposited atop the first Si-containing layer (210), and preferably the second Si-containing layer is a protection layer of the type of silicate layer, more preferably of the type rare earth silicate layer.

According to a further preferred embodiment the second Si-containing layer further comprises aluminum.

Preferably the second Si-containing layer comprises as main components:
Si and O, or
Si, O and N, or
Al, Si and O, or
Al, Si, O and N, or
Al, Si and N as main components.

More preferably the second Si-containing layer is:
a Si—O layer, or
an Al—Si—O layer, or
an Al—Si—N layer.

Preferably the inventive coated substrates are produced by using a method comprising following steps:
providing a substrate having a surface to be coated with a Si-containing coating,
depositing the Si-containing coating on the surface of the substrate provided to be coated with the Si-containing coating, wherein the method used for producing the Si-containing coating comprises at least one of following process steps:
   deposition of the first Si-containing layer by using a chemical vapor deposition process (CVD process), more preferably a plasma enhanced CVD process (PECVD process),
      and/or
deposition of the second Si-containing layer by using a process combining:
   a CVD process and a cathodic arc evaporation physical vapor deposition process (arc PVD process), or
   a PECVD and an arc PVD process:

More preferably the substrate surface to be coated with the Si-containing coating is made of a TMB_{2+z} material or coated with one or more layers comprising a TMB_{2+z} material before deposition of the Si-containing coating.

According to a further preferred embodiment of the present invention the first Si-containing layer 210 and/or the second-containing layer 220 are formed having a multilayer architecture, therefore being formed by more than one layer.

1.-11. (canceled)

12. A coated substrate having a coated surface formed by a substrate surface and a coating on said substrate surface, the coating comprising at least one Si-containing coating film and a base coating film between the substrate and the at least one Si-containing coating film, wherein
the Si-containing coating film comprises a first Si-containing layer and a second Si-containing layer,
the first Si-containing layer is closer to the base coating film than the second Si-containing layer, the first Si-containing layer being a silicon-containing interface layer located directly on an outermost surface of the base coating film to prevent oxidation of the base film,
the first Si-containing layer contains more than 50 atomic % of silicon, and the second Si-containing layer contains more than 50 atomic % of i) Si and O, ii) Si, O and N, iii) Al, Si and O, iv) Al, Si, O and N, or v) Al, Si and N, and
the base coating film comprises at least one layer of TMB_{2+z} where TM is one or more transition metals, B is boron, and z is in a range of 0≤z≤1.

13. The coated substrate according to claim 12, wherein the first Si-containing layer contains ≥99.90 at-% of silicon.

14. The coated substrate according to claim 12, wherein TM is one or more of Ti, Hf and W.

15. The coated substrate according to claim 12, wherein:
the first Si-containing layer has a layer thickness between 30 nm and 30 μm.

16. The coated substrate according to claim 12, wherein the second Si-containing layer has a layer thickness thicker than the first Si-containing layer.

17. The coated substrate according to claim 12, wherein the first Si-containing layer contains diffraction peaks corresponding to pure Si, indicating that the first Si-containing layer is in a partially crystalline state.

18. The coated substrate according to claim 12, wherein the second Si-containing layer is in a X-ray amorphous state.

19. The coated substrate according to claim 12, wherein the second Si-containing layer is atop the first Si-containing layer.

20. The coated substrate according to claim 12, wherein the second Si-containing layer is protection layer of the type of silicate layer.

21. The coated substrate according to claim 12, wherein the substrate is selected from the group consisting of: carbon substrates, boron-rich substrates, substrates comprising composite materials, and substrates consisting of or comprising silicon carbides, zircon carbides, hafnium carbides, boron carbides, and/or other carbides.

22. The coated substrate according to claim 12, wherein the second Si-containing layer (220) contains more than 50 atomic %, of at least one compound selected from silicon oxide, aluminum silicon oxide, and aluminum silicon nitride.

23. The coated substrate according to claim 22, wherein the second Si-containing layer is a Si—O layer, an Al—Si—O layer, or an Al—Si—N layer.

24. The coated substrate according to claim 12, further comprising an additional Si-containing layer between the substrate and the base coating film.

25. The coated substrate according to claim 12, wherein the first Si-containing layer and/or the second Si-containing layer have a multilayer architecture.

26. A method for producing the coated substrate according to claim 12, comprising:
providing a substrate having a surface to be coated,
depositing a base coating film on the surface to be coated, and
depositing a Si-containing coating film on the surface to be coated,
wherein the Si-containing coating film is produced by a method comprising:
depositing a first Si-containing layer by using a chemical vapor deposition process (CVD process),
and/or
depositing a second Si-containing layer by using a process combining i) a CVD process and a cathodic arc evaporation physical vapor deposition process (arc PVD process), or ii) a plasma enhanced chemical vapor deposition process (PECVD) and an arc PVD process.
